(19) United States
(12) Patent Application Publication
(10) Pub. No.: US 2008/0099853 A1
(43) Pub. Date: May 1, 2008

(54) THIN FILM TRANSISTOR AND FABRICATION METHOD THEREOF

(75) Inventors: Chi-Jan Yang, Taipei City (TW); Hsiy-Yu Chang, Changhua County (TW); Yu-Chou Lee, Taipei (TW); Ying-Ming Wu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CHUNGHWA PICTURE TUBES, LTD., Taipei (TW)

(21) Appl. No.: 11/735,441

(22) Filed: Apr. 14, 2007

(30) Foreign Application Priority Data
Oct. 27, 2006 (TW) 95139752

(51) Int. Cl. H01L 29/76; H01L 21/00

(52) U.S. Cl. 257/382; 438/151; 257/E29.226; 257/E21.001

(57) ABSTRACT

A thin film transistor including a substrate, a first buffer layer, a gate, a gate insulation layer, a channel layer, a source and a drain is provided. The first buffer layer is disposed on the substrate and the first buffer is a silicide. The gate covers a portion of the first buffer layer, and the gate includes a first aluminum metal layer and a first protective layer disposed thereon. The gate insulation layer covers the gate, and the channel layer is disposed on part of the gate insulation layer. The source and the drain are disposed on the channel layer and separated form each other. Each of the source and the drain includes a second buffer layer, a second aluminum metal layer and a second protective layer. The second aluminum metal layer is disposed on the second buffer layer and the second protective layer is disposed thereon.

### CROSS-REFERENCE TO RELATED APPLICATION

This application claims the priority benefit of Taiwan application serial no. 95139752, filed Oct. 27, 2006. All disclosure of the Taiwan application is incorporated herein by reference.

### BACKGROUND OF THE INVENTION

1. Field of the Invention

The present invention relates to an active device and a method of fabricating the same, and more particularly, to a thin film transistor and a fabrication method thereof.

2. Description of Related Art

During a conventional fabrication process of semiconductors or a metallizing fabrication process of LCDs, metals such as molybdenum, tantalum, chromium, wolfram or their alloys are generally used as metal layers, wherein aluminum is the most common. Aluminum is the metal of which the Earth has the most abundant reserve. It is inexpensive and characterized by its low resistivity, good adhesion to substrates and good etching characteristics.

However, due to its larger coefficient of thermal expansion, when a thermal fabrication process is performed, such as chemical vapor deposition (CVD) or annealing, a mismatch of thermal strain between an aluminum layer and a substrate is created. The aluminum layer receives such stress that aluminum atoms are forced to diffuse along the boundaries of aluminum chips and small protrusions (or aluminum hillocks) are formed on the aluminum layer. Small protrusions may cause electric leakage, short circuits, broken circuits, or affect the performance of FETs.

A conventional method to avoid creating small protrusions is adding some metal material with a melting point higher than that of aluminum, for example, neodymium, titanium, zirconium, tantalum, silicon, or copper. The aluminum-neodymium alloy made by the Kobelco Company is the most well-known and the most commonly used. Nonetheless, neodyminum is a costly and rare metal and has a high resistance; hence, the field of this conventional method can apply is limited.

The second method to avoid creating small protrusions is covering a protective layer of a high melting point on the top of the aluminum layer. This protective layer covers the boundaries of aluminum chips to mitigate the forming of small protrusions. For instance, Taiwan Patent No. 1233178 discloses a gate layer without small protrusions and a fabrication method thereof. The principle of the fabrication method is forming an aluminum layer to be covered by another aluminum layer containing nitrogen (such as nitro-aluminum or AINxOy).

Taking Taiwan Patent No. I232541 as another example, its claims 12 and 13 disclose an electronic element. Its principle is forming a protective layer over the aluminum layer to avoid creating aluminum hillocks. The protective layer includes metals such as molybdenum, MoN, titanium or their alloys. Besides, it can be known from U.S. Pat. No. 6,333,518 that molybdenum, MoW, MoTa and MoNb may all be used to cover an aluminum layer so as to mitigate the forming of small protrusions.

On the other hand, because aluminum is very easy to be oxidized or corroded, it requires a solution to this problem. For instance, U.S. Pat. No. 6,921,698 discloses a thin film transistor, wherein MoNb is utilized as the gate instead of aluminum or aluminum alloys. Another example is U.S. Patent No. 20040263706, which discloses an array substrate, and alloys of tantalum, titanium or molybdenum are formed on the aluminum layer to protect it.

The third method to avoid creating small protrusions is disposing a buffer layer between the aluminum layer and the substrate. The thermal expansion coefficient of the buffer layer is lower than that of the aluminum layer, so that the said mismatch of thermal strain can be alleviated. For instance, the gate of a thin film transistor disclosed in Taiwan Patent No. 1246874 includes a buffer layer and an aluminum layer, wherein the buffer layer includes materials such as AlNx, AlOx or AlOxNy. Furthermore, the said Taiwan Patent No. 1232541 also discloses a similar method, wherein AlNd is used as the buffer layer and also achieves the same effect.

As described above, although there is a lot of prior art available, the industry still needs better solutions to deal with the problem of creating small protrusions with less cost.

### SUMMARY OF THE INVENTION

In view of the above, the present invention provides a thin film transistor to reduce small protrusions that are formed on an aluminum metal layer in a gate, a source and a drain.

Besides, the invention further provides a fabrication method of a thin film transistor and utilizes a low-cost technical means to reduce small protrusions that are formed on the aluminum metal layer in the gate, the source and the drain.

The invention provides a thin film transistor, which includes a substrate, a first buffer layer, a gate, a gate insulation layer, a channel layer, a source, and a drain. The first buffer layer is disposed on the substrate, and the first buffer layer is a silicide. The gate covers a portion of the first buffer layer. The gate includes a first aluminum layer and a first protective layer, wherein the first protective layer is disposed on the first aluminum metal layer. The gate insulation layer covers the gate, and the channel layer is disposed on part of the gate insulation layer over the gate. The source and the drain are disposed on the channel layer and separated from each other. Each of the source and the drain includes a second buffer layer, a second aluminum metal layer and a second protective layer. The second aluminum metal layer is disposed on the second buffer layer, and the second protective layer is disposed on the second aluminum metal layer.

In one embodiment of the present invention, silicide includes silicon oxide or silicon nitride.

In one embodiment of the invention, the thickness of the first buffer layer is 100 to 500 angstroms.

In one embodiment of the invention, the second buffer layer includes molybdenum or molybdenum-niobium (MoNb).

In one embodiment of the invention, the thickness of the second buffer layer is 100 to 1000 angstroms.

In one embodiment of the invention, the first protective layer includes molybdenum or MoNb.

In one embodiment of the invention, the thickness of the first protective layer is 100 to 1000 angstroms.

In one embodiment of the invention, the second protective layer includes molybdenum or MoNb.

In one embodiment of the invention, the thickness of the first protective layer is 100 to 1000 angstroms.

In one embodiment of the invention, the thickness of the second protective layer is 100 to 1000 angstroms.

In one embodiment of the invention, the thickness of the first aluminum metal layer is 1000 to 4000 angstroms.

In one embodiment of the invention, the thickness of the second aluminum metal layer is 1000 to 4000 angstroms.

The invention provides a fabrication method of a thin film transistor. First, a first buffer layer is formed on a substrate. The first buffer layer is a silicide, and covers the whole substrate. Then, a first aluminum metal layer and a first protective layer are formed in order on the first buffer layer to constitute a gate. Afterwards, a gate insulation layer is formed to cover the gate. Next, a channel layer is formed on part of the gate insulation layer over the gate. Then, a second buffer layer, a second aluminum metal layer and a second protective layer are formed in order on the channel layer to constitute a source and a drain separated from each other.

In one embodiment of the invention, the pressure used for forming the first protective layer is 0.1 to 1 Pa, the power density is 0.2 to 10.9 w/cm², and the temperature is 25° C. to 150° C.

In one embodiment of the invention, the pressure used for forming the second protective layer is 0.1 to 1 Pa, the power density is 0.2 to 10.9 w/cm², and the temperature is 25° C. to 150° C.

In one embodiment of the invention, the pressure used for forming the second buffer layer is 0.1 to 1 Pa, the power density is 0.2 to 10.9 w/cm², and the temperature is 25° C. to 150° C.

In one embodiment of the invention, the pressure used for forming the first aluminum metal layer is 0.1 to 1 Pa, the power density is 0.2 to 10.9 w/cm², and the temperature is 25° C. to 150° C.

In one embodiment of the invention, the pressure used for forming the second aluminum metal layer is 0.1 to 1 Pa, the power density is 0.2 to 10.9 w/cm², and the temperature is 25° C. to 150° C.

The present invention utilizes the buffer layers and the protective layers to restrain small protrusions from being formed on the aluminum metal layers. Hence, the reliability of the thin film transistor can be elevated. Moreover, compared with the prior art, the invention requires less cost for materials and its fabrication method.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1E are top views illustrating the fabrication flowchart of a thin film transistor in one embodiment of the present invention.

FIGS. 2A to 2E are respective cross-sectional views along sectioning lines I-I in FIGS. 1A to 1E.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In view of the drawbacks in the prior art, a three-layer structure of buffer layer, aluminum metal layer and protective layer is provided in the present invention, which can restrain small protrusions from being formed on the aluminum layers because of heat. Further, when the three-layer structure is applied in thin film transistors, the first buffer layer completely covers the substrate, so as to mitigate the shape change of the substrate.

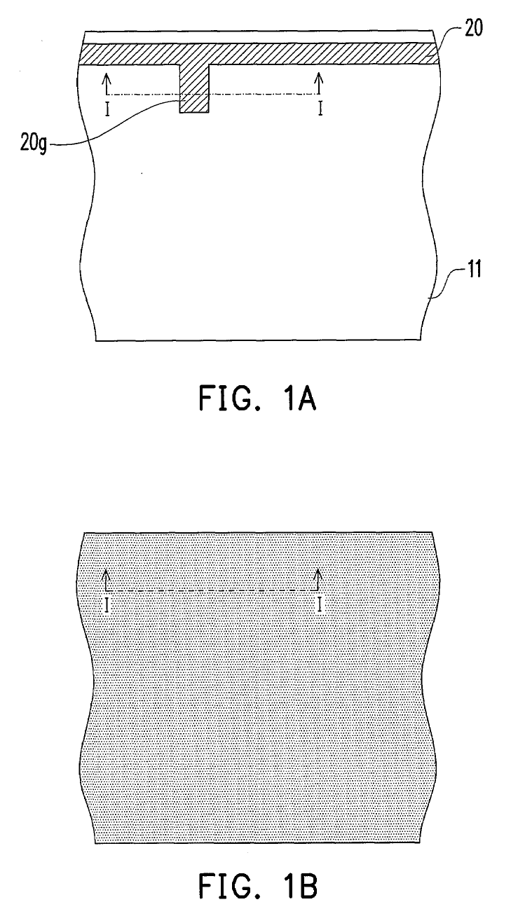

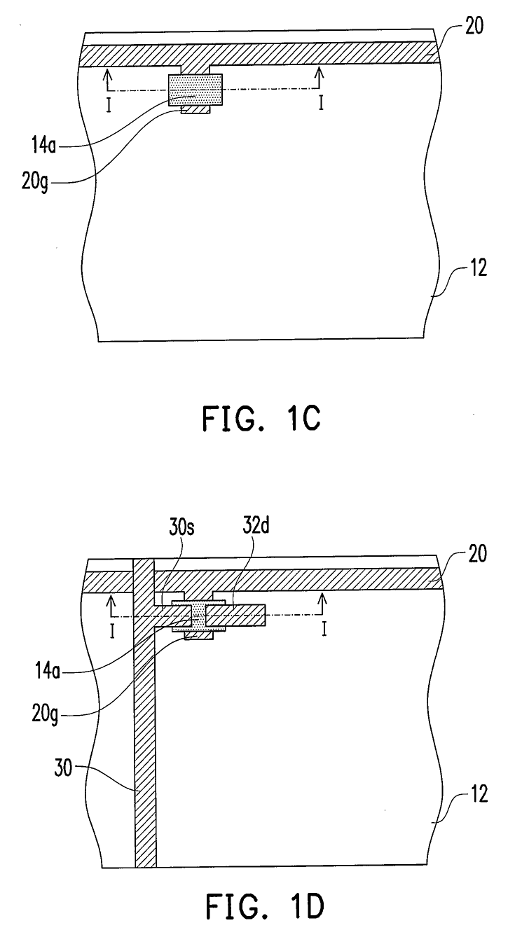

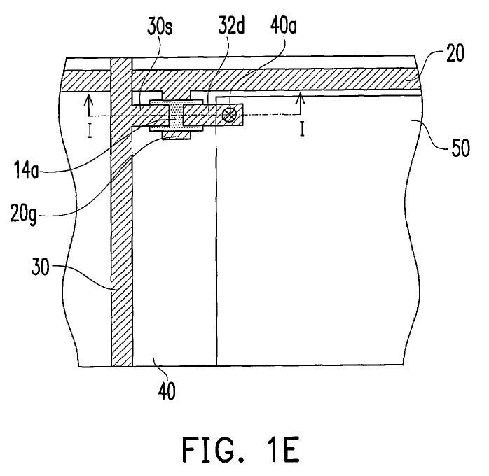

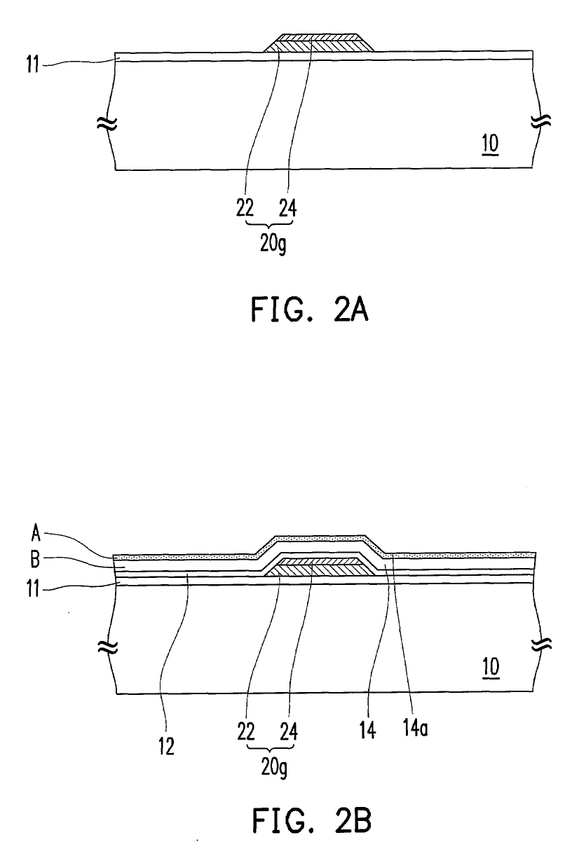

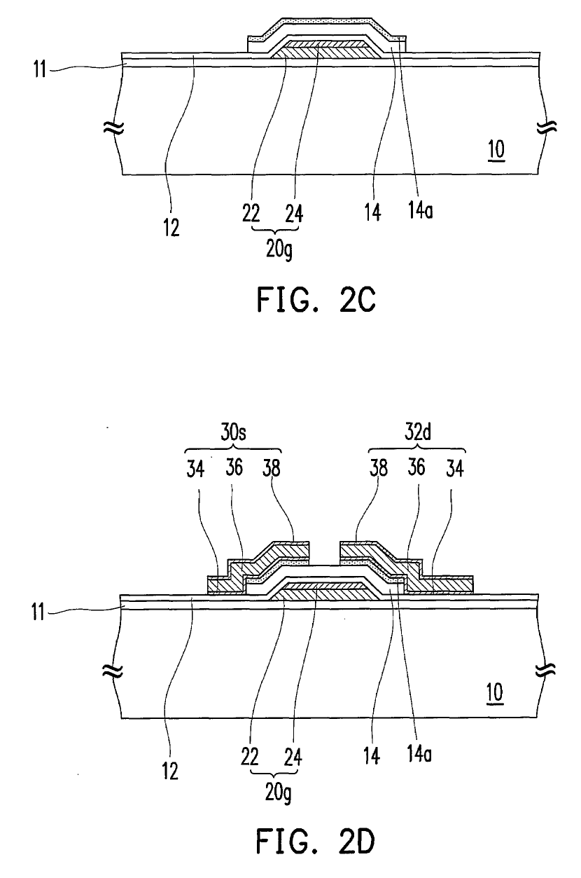

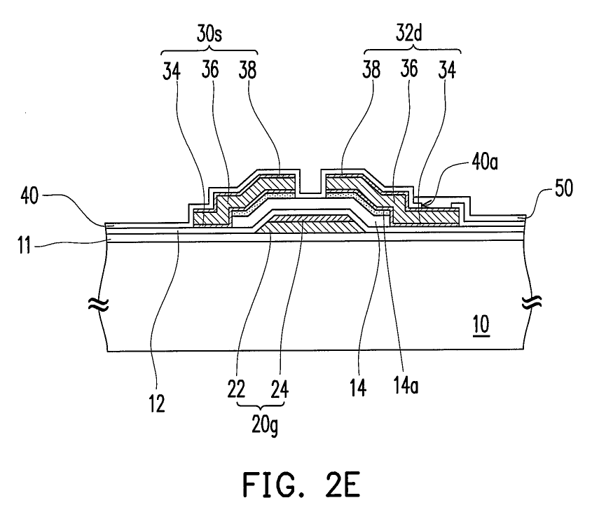

FIGS. 1A to 1E are top views illustrating the fabrication flowchart of a thin film transistor in one embodiment of the invention. FIGS. 2A to 2E are respective cross-sectional views along sectioning lines I-I in FIGS. 1A to 1E.

Referring to FIGS. 1A and 2A, the fabrication method of a thin film transistor in the present embodiment includes the following steps. First, a first buffer layer 11 is formed on a substrate 10, wherein the method adopted for forming the first buffer layer 11 may be plasma enhanced chemical vapor deposition (CVD) process. Further, the thickness of the formed first buffer layer 11 may be between 100 and 500 angstroms. Then, a first aluminum metal layer 22 and a first protective layer 24 are formed in order on the first buffer layer 11 to constitute a gate 20g.

More specifically, the method of forming the first aluminum metal layer 22 and the first protective layer 24 includes that an aluminum metal material layer (not illustrated) and a protective material layer (not illustrated) are first formed on the first buffer layer 11. Then, a photolithography process and an etching process are performed on the aluminum metal material layer and the protective material layer to form the first aluminum metal layer 22 and the first protective layer 24. Besides, the first aluminum metal layer 22 and the first protective layer 24 can be formed by a sputtering process, wherein the pressure used for forming the first protective layer 24 may be 0.1 to 1 Pa, the power density may be 0.2 to 10.9 w/cm², and the temperature may be 25° C. to 150° C. Furthermore, the pressure used for forming the first aluminum metal layer 22 may be 0.1 to 1 Pa, the power density may be 0.2 to 10.9 w/cm², and the temperature may be 25° C. to 150° C.

Afterwards, referring to FIGS. 1B and 2B, a gate insulation layer 12 is formed to cover the gate 20g. The insulation layer 12 may be made of silicon oxide or silicon nitride, and may be formed by the CVD process. Subsequently, the gate insulation layer 12, a channel material layer A and an ohmic contact material layer B are formed in order on top of the gate 20g. The material of the gate insulation layer 12 may be silicon nitride, while the material of the channel material layer A may be amorphous silicon. The ohmic contact material layer B may be an N-type doped silicon. Additionally, the gate insulation layer 12 may be formed by methods such as chemical vapor deposition (CVD) process.

Referring to FIGS. 1C and 2C, subsequently a photolithography process and an etching process are performed to pattern the channel material layer A and the ohmic contact material layer B such that a channel layer 14 and an ohmic contact layer 14a are formed.

Afterwards, referring to FIGS. 1D and 2D, a second insulation layer 34, a second aluminum metal layer 36 and a second protective layer 38 are formed in order on the channel layer 14 to constitute a source 30s and a drain 32d, which are separated from each other. The method of forming the source 30s and the drain 32d includes that a buffer material layer (not illustrated), an aluminum metal material layer (not illustrated) and a protective material layer (not illustrated) are formed in order over the substrate 10. Then, a photolithography process and an etching process are performed on the buffer material layer, the aluminum metal material layer and the protective material layer to form the second buffer layer 34, the second aluminum metal layer 36 and the second protective layer 38. Furthermore, the pressure used for forming the second aluminum metal layer 36 may be 0.1 to 1 Pa, the power density may be 0.2 to 10.9 w/cm², and the temperature may be 25° C. to 150° C.

In the present embodiment of the invention, the pressure used for forming the second protective layer 38 is 0.1 to 1 Pa, the power density is 0.2 to 10.9 w/cm², and the temperature is 25° C. to 150° C. Up to this step, the fabrication method of the thin film transistor in the present invention is completed.

Next, referring to FIGS. 1E and 2E, when the thin film transistors is applied to a pixel structure of a thin film transistor array substrate, the subsequent fabrication further includes that a third protective layer 40 and a pixel electrode 50 are formed in order over the substrate 10, wherein the pixel electrode 50 and the drain 32d are electrically connected. Further, for persons ordinarily skilled in the art, the materials and the forming method of the third protective layer 40 and the pixel electrode 50 are well-known, and thus will not be reiterated herein. Besides, other details relating to the structure of the thin film transistor structure will be described in detail later.

Referring to both FIGS. 1E and 2E simultaneously, the thin film transistor comprises the substrate 10, the first buffer layer 11, the gate 20g, the gate insulation layer 12, the channel layer 14, the source 30s and the drain 32d. The first buffer layer 11 completely covers the substrate 10, and the first buffer layer 11 is silicide, which includes silicon oxide or silicon nitride. Further, the first buffer layer 11 is preferably silicon oxide because silicon oxide is transparent. The thickness of the first buffer layer 11 may be 100 to 500 angstroms.

A portion of the first buffer layer 11 is covered by the gate 20g, which includes a first aluminum metal layer 22 and a first protective layer 24, wherein the first aluminum metal layer 22 is disposed on the first buffer layer 11, and the first protective layer 24 is disposed on the first aluminum metal layer 22. Moreover, the first aluminum layer 22 and the first protective layer 24 also constitute a scan line 20. The thickness of the first aluminum layer 22 may be 1000 to 4000 angstroms, and the first protective layer 24 is molybdenum or MoNb. The thickness of the first protective layer 24 is 100 to 1000 angstroms. Besides, because the first protective layer 24 is disposed on the first aluminum layer 22, in the subsequent fabrication process, the first protective layer 24 will restrain small protrusions from being formed on the aluminum layer 22.

Additionally, because the first aluminum metal layer 22 is disposed on the first buffer layer 11, in the subsequent fabrication processes such as annealing and chemical vapor deposition, the thermal expansion range of the first aluminum metal layer 22 can be restrained so as to reduce small protrusions. Because the first buffer layer 11 completely covers the substrate 10, the first buffer layer 11 can also reduce the warping range of the substrate 10. Further, the first buffer layer 11 can also mitigate the diffusing of the impurities of the substrate 10 to the first aluminum metal layer 22. Hence, materials with a higher percentage of impurities can be chosen for the substrate 10 to lower costs.

The gate insulation layer 12 covers the gate 20g, and the channel layer 14 is disposed on part of the gate insulation layer 12 over the gate 20g. The source 30s and the drain 32d are disposed on the channel layer 14 and separated from each other. Generally speaking, an ohmic contact layer 14a is further disposed between the source 30s and the channel layer 14, and between the drain 32d and the channel layer 14.

As shown in FIG. 1E, the source 30s and the drain 32d both include the second buffer layer 34, the second aluminum metal layer 36 and the second protective layer 38, wherein the second aluminum metal layer 36 is disposed on the second buffer layer 34, and the second protective layer 38 is disposed on the second aluminum metal layer 36. Additionally, the second buffer layer 34, the second aluminum metal layer 36 and the second protective layer 38 further constitute a date line 30. In the present embodiment, the second buffer layer 34 may be molybdenum or MoNb, and the thickness of the second buffer may be 100 to 1000 angstroms. The thickness of the second aluminum metal layer can be 1000 to 4000 angstroms. Besides, the second protective layer 38 may be molybdenum or MoNb, and the thickness of the second protective layer can be 100 to 1000 angstroms. Likewise, the function of the second protective layer 38 is similar to that of the first protective layer 24, and the function of the second buffer layer 34 is similar to that of the first buffer layer 11.

As described above, when the thin film transistor is applied in a pixel structure of the thin film transistor array substrate, the pixel structure further includes a third protective layer 40 and a pixel electrode 50, wherein the third protective layer 40 is disposed over the substrate 10 and covers the thin film transistor. Moreover, the third protective layer 40 has a contact hole 40a, which exposes the drain 32d. The pixel electrode 50 is disposed on the third protective layer 40, and is electrically connected with the drain 32d.

Because the second buffer layer 34 and the second protective layer 38 are disposed in the thin film transistor of the present invention, the thin film transistor can mitigate the forming of small protrusions on the source 30s, the drain 32d and the data line 30, so as to increase the reliability of the thin film transistor.

To sum up the above, the thin film transistor and the fabrication method thereof disclosed in the present invention have at least the following advantages:

1. The invention adopts buffer layers and protective layers to restrain small protrusions from being formed on the aluminum metal layers.

2. The first buffer layer on the substrate can mitigate the diffusing of the impurities of the substrate to the aluminum metal layers. Hence, the manufacturer can choose substrates of lower qualities to reduce the cost for materials.

3. The fabrication method of the thin film transistor in the invention can achieve the effect of reducing small protrusions with a low-cost material and less expensive fabrication conditions so as to increase the reliability of the thin film transistor.

The foregoing description of the embodiments of the present invention has been presented for purposes of illustration and description. It is not intended to be exhaustive or to limit the invention to the precise form or to exemplary embodiments disclosed. It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A thin film transistor, comprising:
a substrate;
a first buffer layer, disposed on the substrate, and the first buffer layer is a silicide;
a gate, covering a portion of the first buffer layer and comprising:
a first aluminum metal layer;
a first protective layer, disposed on the first aluminum layer;
a gate insulation layer, covering the gate;
a channel layer, disposed on part of the gate insulation layer on top of the gate; and
a source and a drain, disposed on the channel layer and separated from each other, wherein each of the source and the drain comprises:
a second buffer layer;
a second aluminum metal layer, disposed on the second buffer layer; and
a second protective layer, disposed on the second aluminum metal layer.

2. The thin film transistor as claimed in claim 1, wherein the silicide comprises a silicon oxide or a silicon nitride.

3. The thin film transistor as claimed in claim 1, wherein the thickness of the first buffer layer is 100 to 500 angstroms.

4. The thin film transistor as claimed in claim 1, wherein the second buffer layer comprises molybdenum or molybdenum-niobium (MoNb).

5. The thin film transistor as claimed in claim 4, wherein the thickness of the second buffer layer is 100 to 1000 angstroms.

6. The thin film transistor as claimed in claim 1, wherein the first protective layer comprises molybdenum or MoNb.

7. The thin film transistor as claimed in claim 6, wherein the thickness of the first protective layer is 100 to 1000 angstroms.

8. The thin film transistor as claimed in claim 1, wherein the second protective layer comprises molybdenum or MoNb.

9. The thin film transistor as claimed in claim 8, wherein the thickness of the second protective layer is 100 to 1000 angstroms.

10. The thin film transistor as claimed in claim 1, wherein the thickness of the first aluminum metal layer is 1000 to 4000 angstroms.

11. The thin film transistor as claimed in claim 1, wherein the thickness of the second aluminum metal layer is 1000 to 4000 angstroms.

12. A fabrication method of a thin film transistor, comprising:
forming a first buffer layer on a substrate, wherein the first buffer layer is a silicide and covers the whole substrate;
forming in order a first aluminum metal layer and a first protective layer on the first buffer layer to constitute a gate;
forming a gate insulation layer to cover the gate;
forming a channel layer on part of the gate insulation layer over the gate; and
forming in order a second buffer layer, a second aluminum metal layer and a second protective layer to constitute a source and a drain, which are separated from each other.

13. The fabrication method of the thin film transistor as claimed in claim 12, wherein the pressure used for forming the first protective layer is 0.1 to 1 Pa, the power density is 0.2 to 10.9 w/cm², and the temperature is 25° C. to 150° C.

14. The fabrication method of the thin film transistor as claimed in claim 12, wherein the pressure used for forming the second protective layer is 0.1 to 1 Pa, the power density is 0.2 to 10.9 w/cm², and the temperature is 25° C. to 150° C.

15. The fabrication method of the thin film transistor as claimed in claim 12, wherein the pressure used for forming the second buffer layer is 0.1 to 1 Pa, the power density is 0.2 to 10.9 w/cm², and the temperature is 25° C. to 150° C.

16. The fabrication method of the thin film transistor as claimed in claim 12, wherein the pressure used for forming the first aluminum layer is 0.1 to 1 Pa, the power density is 0.2 to 10.9 w/cm², and the temperature is 25° C. to 150° C.

17. The fabrication method of the thin film transistor as claimed in claim 12, wherein the pressure used for forming the second aluminum layer is 0.1 to 1 Pa, the power density is 0.2 to 10.9 w/cm², and the temperature is 25° C. to 150° C.
